(19) United States
(12) Patent Application Publication
(10) Pub. No.: US 2015/0030972 A1
(43) Pub. Date: Jan. 29, 2015

(54) PHOTO-SENSITIVE RESIN COMPOSITION FOR BEZEL OF TOUCH SCREEN MODULE AND BEZEL FOR TOUCH SCREEN MODULE USING THE SAME

(71) Applicant: SAMSUNG ELECTRO-MECHANICS CO., LTD., Suwon-Si (KR)

(72) Inventors: Kee Su Jeon, Suwon-Si (KR); Jang Bae Son, Suwon-Si (KR); Jai Hyoung Gil, Suwon-Si (KR); Kyoung-Jin Jeong, Suwon-Si (KR)

(73) Assignee: SAMSUNG ELECTRO-MECHANICS CO., LTD., Suwon-Si (KR)

(21) Appl. No.: 14/514,343

(22) Filed: Oct. 14, 2014

Related U.S. Application Data
(63) Continuation of application No. 13/845,039, filed on Mar. 17, 2013, now abandoned.

(30) Foreign Application Priority Data
Dec. 28, 2012 (KR) 10-2012-0157262

(51) Int. Cl. G06F 1/16; G03F 7/004

(52) U.S. Cl. CPC G06F 1/1601; G03F 7/004
USPC 430/18; 430/270.1

(57) ABSTRACT

This invention relates to a photo-sensitive resin composition for a bezel of a touch screen module, including a colorant composed of surface-modified TiO₂, a binder resin, a dispersing agent, a photopolymerizable compound, a photoinitiator, and a solvent, and having a viscosity of 2˜30 cps and a solid content of 50˜90 mass %, and to a bezel for a touch screen module using the same. The photo-sensitive resin composition can exhibit superior dispersion stability, and even when a thin pattern layer is formed therefrom, whiteness represented by L* can be 85% or more, and thus the photo-sensitive resin composition can be effectively utilized in a bezel for a touch screen module.

### CROSS-REFERENCE TO RELATED APPLICATION

This application claims the benefit of Korean Patent Application No. 10-2012-0157262, filed Dec. 28, 2012, entitled “Photo-sensitive resin composition for bezel of touch screen module and bezel for touch screen module using the same,” which is hereby incorporated by reference in its entirety into this application.

### BACKGROUND OF THE INVENTION

1. Technical Field

The present invention relates to a photo-sensitive resin composition for a bezel of a touch screen module, and to a bezel for a touch screen module using the same.

2. Description of the Related Art

With the recent user demand for user-friendly electronic products, the use of touch screens, by which information is input by touching the screen of an electronic product directly, is becoming more common. In particular, the commercialization and drastic advancement of smart phones and tablet PCs contributed greatly to the popularization and development of touch screen panels. Touch screen devices include not only the concept of touch input but also the concept of applying the user's intuitive experience to an interface and providing a variety of feedback.

Touch screen devices are advantageous because they can be easily operated in small spaces, their specifications can be easily changed, they have high user recognition, and they are highly compatible with IT devices. Thereby, everyone may easily and rapidly learn to use electronic devices that have touch screens, making it possible to widely apply touch screens to devices used in a variety of fields including industry, transportation, hospitality and dining, healthcare, mobile devices, etc.

In such a touch screen device, the operation mode of a touch screen module (TSM) was changed from a resistive type to a capacitive type a few years ago. A capacitive TSM is converted into a window integrated TSM having a single OCA layer 50 as illustrated in FIG. 1, or into an on-cell or in-cell TSM, in place of GFF having three OCA (Optically Clear Adhesive) layers or GF2 having two OCA layers.

As illustrated in FIG. 1, the window integrated TSM is configured such that a substrate 10 is coated with a bezel 30 and then with a sensor electrode 20. As illustrated in FIG. 2, because the sensor electrode 20 is very thin, the bezel 30 should be thin to reduce a difference in thickness. To make the thin bezel 3 and to form a pattern, ink has to be prepared using photo-sensitive components. Also, the viscosity of the ink should be sufficiently low.

Upon manufacturing the TSM, bezels having various colors are used for decoration. Ink using TiO₂ as a pigment is mainly adopted to show a white color. Because of the high specific gravity of TiO₂, it is difficult to sufficiently ensure dispersion stability of a dispersion solution and ink at low viscosity to form a thin bezel during a mass production process.

For example, the dispersing of TiO₂ is mainly performed by dissolving an appropriate wet dispersing agent in a solvent, adding TiO₂, and then dispersing it using a homogenizer or a bead mill. As such, a binder resin may be added to the solvent together with the dispersing agent. In order to obtain sufficient dispersibility and dispersion stability, a large amount of wet dispersing agent has to be typically added. However, problems in which TiO₂ may easily flocculate and precipitate occur because of the high specific gravity of TiO₂. Furthermore, as the dispersing agent is added in a large amount, the properties of a coating film may undesirably deteriorate.

Also, a conventional capacitive TSM such as GFF or GF2 is mainly configured such that OCA is applied after the formation of the bezel. In this case, the total thickness of the TSM may undesirably increase due to additional OCA. Moreover, a bezel is conventionally manufactured using a screen printing process, and thus has a thickness ranging from about 20 μm to about 60 μm, which is regarded as thick when a sensor electrode is directly formed thereon. This method is difficult to apply to mobile phones, tablet PCs, TV sets, etc., which should have a thin film.

### SUMMARY OF THE INVENTION

Culminating in the present invention, intensive and thorough research with the aim of solving the problems occurring in the related art resulted in the finding that the use of a photo-sensitive resin composition containing a high concentration of TiO₂ which is surface-modified so as to obtain superior dispersibility enables whiteness represented by L* to be 85% or more even when a bezel for a touch screen module is formed to a thickness of 15 μm or less.

Accordingly, a first aspect of the present invention is to provide a photo-sensitive resin composition for a bezel of a touch screen module.

A second aspect of the present invention is to provide a bezel of a touch screen module using the above photo-sensitive resin composition.

In order to accomplish the above first aspect of the present invention, a photo-sensitive resin composition for a bezel of a touch screen module (hereinafter, referred to as “the first invention”) is provided, which includes a colorant composed of surface-modified TiO₂, a binder resin, a dispersing agent, a photopolymerizable compound, a photoinitiator, and a solvent, and has a viscosity of 2˜30 cps and a solid content of 50˜90 mass %.

In the first invention, the photo-sensitive resin composition may include 45˜80 mass % of a colorant composed of surface-modified TiO₂, 1˜15 mass % of a binder resin, 1˜10 mass % of a dispersing agent, 1˜10 mass % of a photopolymerizable compound, 1˜5 mass % of a photoinitiator, and 15˜43 mass % of a solvent.

In the first invention, the TiO₂ may be surface-treated with at least one selected from the group consisting of SiO₂, Al₂O₃, ZrO₂, ZnO and an organic material.

In the first invention, the surface-treated TiO₂ may have 75˜95 mass % of TiO₂ core.

In the first invention, the colorant may be used in an amount of 50˜90 mass % based on the solid content of the composition.

In the first invention, the photo-sensitive resin composition may further include at least one additive selected from the group consisting of a polymer compound, a curing agent, a surfactant, an adhesion accelerator, an antioxidant, a UV absorber, and an anti-flocculating agent.

In order to accomplish the above second aspect of the present invention, a bezel for a touch screen module (hereinafter, referred to as “the second invention”) is provided, which includes a pattern layer formed by applying the photo-sensitive resin composition according to the first invention on a substrate, and performing exposure and development in a predetermined pattern.

In the second invention, the bezel may have a thickness of 3˜15 μm.

In the second invention, the bezel may have a whiteness of 85% or more as measured by reflectance.

### BRIEF DESCRIPTION OF THE DRAWINGS

The above and other aspects, features and other advantages of the present invention will be more clearly understood from the following detailed description when taken in conjunction with the accompanying drawings, in which:

FIG. 1 is a cross-sectional view illustrating a typical window integrated touch screen module; and

FIG. 2 is a cross-sectional view illustrating a sensor electrode formed on a glass substrate and a bezel in the typical window integrated touch screen module.

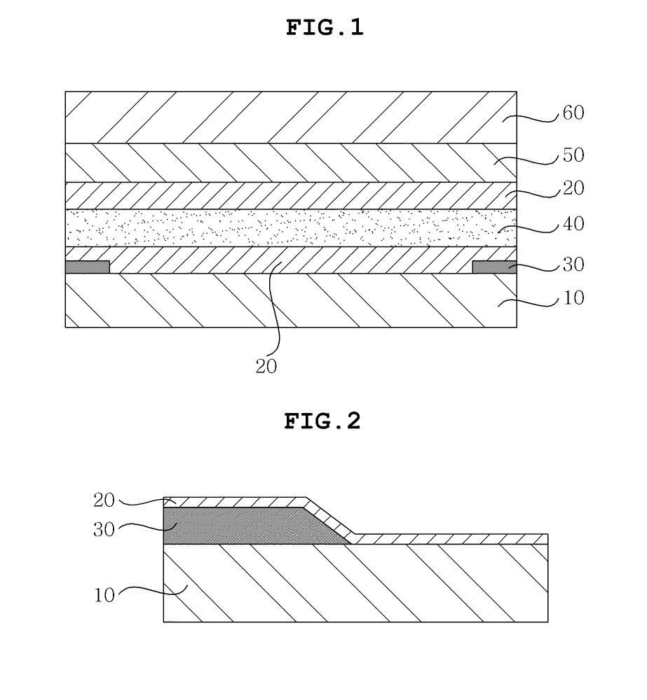

### DESCRIPTION OF SPECIFIC EMBODIMENTS

Before the present invention is described in more detail, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention. It is noted that, the embodiments of the present invention are merely illustrative, and are not construed to limit the scope of the present invention, and thus there may be a variety of equivalents and modifications able to substitute for them at the point of time of the present application.

In the following description, it is to be noted that embodiments of the present invention are described in detail so that the present invention may be easily performed by those skilled in the art, and also that, when known techniques related with the present invention may make the gist of the present invention unclear, a detailed description thereof will be omitted.

According to the present invention, a photo-sensitive resin composition for a bezel of a touch screen module includes a colorant (A) composed of surface-modified TiO₂, a binder resin (B), a dispersing agent (C), a photopolymerizable compound (D), a photoinitiator (E), and a solvent (F).

Colorant (A)

The colorant is a white pigment including TiO₂. TiO₂ is very inexpensive and has a high refractive index and thus high reflectance, so that it may be effectively used as a white colorant. TiO₂ may have a rutile structure. TiO₂ with a rutile structure has superior whiteness and thus may be effectively employed.

TiO₂ which is a white pigment may be subjected to resin treatment, surface treatment using a pigment derivative having an acid group or a basic group, graft treatment to the surface of a pigment using a polymer compound, atomization treatment using sulfuric acid or cleaning treatment using an organic solvent or water to remove impurities, removal treatment of ionic impurities using ion exchange, etc., as necessary.

The surface of TiO₂ may be treated with at least one selected from the group consisting of SiO₂, Al₂O₃, ZrO₂, ZnO and an organic material. The surface treatment of TiO₂ may decrease photocatalytic activity of TiO₂ and may also increase reflected luminance The surface-treated TiO₂ may have 75˜95 mass % of TiO₂ core. In the case where the surface of the TiO₂ core is treated in the above range, whiteness may increase and reflected luminance may become superior.

Specific examples of TiO₂ may include R-101, R-102, R-103, R-104, R-105, R-350, R-706, R-794, R-796, TS-6200, R-900, R-902, R-902+, R-931, and R-960, available from Dupont; R-FC5, TR81, and TR88, available from Huntman; and CR-57 available from ISK.

The colorant which is a white pigment is included in an amount of 50˜90 mass %, and preferably 60˜70 mass %, based on the solid content of the photo-sensitive resin composition. The amount of the colorant is set to 45˜80 mass % so as to maintain the above solid content and to achieve appropriate coating workability of the composition. When the photo-sensitive resin composition according to the present invention including the colorant in the above amount range is thinly applied upon manufacturing a bezel for TSM, high whiteness may be obtained. In the present invention, the solid content means the amount of components except for the solvent

Binder Resin (B)

The binder resin may be used without limitation so long as it is typical in the art. The kind of binder resin is not particularly limited so long as it is dissolved in the solvent of the invention, binds the colorant and is dissoluble in an alkaline developing solution.

The binder resin may include, for example, a copolymer of a carboxyl group-containing monomer and a comonomer copolymerizable with the monomer.

Examples of the carboxyl group-containing monomer may include unsaturated carboxylic acid, including unsaturated polycarboxylic acid having one or more carboxyl groups in the molecule thereof, such as unsaturated monocarboxylic acid, unsaturated dicarboxylic acid, unsaturated tricarboxylic acid, etc.

Examples of the unsaturated monocarboxylic acid include acrylic acid, methacrylic acid, crotonic acid, α-chloroacrylic acid, cinammic acid, etc.

Examples of the unsaturated dicarboxylic acid may include maleic acid, fumaric acid, itaconic acid, citraconic acid, mesaconic acid, etc.

The unsaturated polycarboxylic acid may be an acid anhydride, specific examples of which may include maleic anhydride, itaconic anhydride, citraconic anhydride, etc. Also, the unsaturated polycarboxylic acid may be its mono(2-methacryloyloxyalkyl)ester, specific examples of which may include mono(2-acryloyloxyethyl)succinate, mono(2-methacryloyloxyethyl)succinate, mono(2-acryloyloxyethyl)phthalate, mono(2-methacryloyloxyethyl)phthalate, etc. The unsaturated polycarboxylic acid may be mono(meth)acrylate of a both-terminal dicarboxy polymer, specific examples of which may include co-carboxy polycaprolactone monoacrylate, co-carboxy polycaprolactone monomethacrylate, etc.

These carboxyl group-containing monomers may be used alone or in combination of two or more.

Examples of the comonomer copolymerizable with the carboxyl group-containing monomer may include aromatic vinyl compounds, including styrene, α-methylstyrene, o-vinyltoluene, m-vinyltoluene, p-vinyltoluene, p-chlorostyrene, o-methoxystyrene, m-methoxystyrene, p-methoxystyrene, o-vinylbenzyl methyl ether, m-vinylbenzyl methyl ether, p-vinylbenzyl methyl ether, o-vinylbenzyl glycidyl ether, m-vinylbenzyl glycidyl ether, p-vinylbenzyl glycidyl ether, indene, etc.; unsaturated carboxylic acid esters, including methyl acrylate, methyl methacrylate, ethyl acrylate, ethyl methacrylate, n-propyl acrylate, n-propyl methacrylate, i-propyl acrylate, i-propyl methacrylate, n-butyl acrylate, n-butyl methacrylate, i-butyl acrylate, i-butyl methacrylate, sec-butyl acrylate, sec-butyl methacrylate, t-butyl acrylate, t-butyl methacrylate, 2-hydroxyethyl acrylate, 2-hydroxyethyl methacrylate, 2-hydroxypropyl acrylate, 2-hydroxypropyl methacrylate, 3-hydroxypropyl acrylate, 3-hydroxypropyl methacrylate, 2-hydroxybutyl acrylate, 2-hydroxybutyl methacrylate, 3-hydroxybutyl acrylate, 3-hydroxybutyl methacrylate, 4-hydroxybutyl acrylate, 4-hydroxybutyl methacrylate, allyl acrylate, allyl methacrylate, benzyl acrylate, benzyl methacrylate, cyclohexyl acrylate, cyclohexyl methacrylate, phenyl acrylate, phenyl methacrylate, 2-methoxyethyl acrylate, 2-methoxyethyl methacrylate, 2-phenoxyethyl acrylate, 2-phenoxyethyl methacrylate, methoxydiethylene glycol acrylate, methoxydiethylene glycol methacrylate, methoxytriethylene glycol acrylate, methoxytriethylene glycol methacrylate, methoxypropylene glycol acrylate, methoxypropylene glycol methacrylate, methoxydipropylene glycol acrylate, methoxydipropylene glycol methacrylate, isobornyl acrylate, isobornyl methacrylate, dicyclopentadienyl acrylate, dicyclopentadiethyl methacrylate, 2-hydroxy-3-phenoxypropyl acrylate, 2-hydroxy-3-phenoxypropyl methacrylate, glycerol monoacrylate, glycerol monomethacrylate, etc.; unsaturated carboxylic acid aminoalkylesters, including 2-aminoethyl acrylate, 2-aminoethyl methacrylate, 2-dimethylaminoethyl acrylate, 2-dimethylaminoethyl methacrylate, 2-aminopropyl acrylate, 2-aminopropyl methacrylate, 2-dimethylaminopropyl acrylate, 2-dimethylaminopropyl methacrylate, 3-aminopropyl acrylate, 3-aminopropyl methacrylate, 3-dimethylaminopropyl acrylate, 3-dimethylaminopropyl methacrylate, etc.; unsaturated carboxylic acid glycidylesters, including glycidyl acrylate, glycidyl methacrylate, etc.; carboxylic acid vinylesters, including vinyl acetate, vinyl propionate, vinyl butyrate, vinyl benzoate, etc.; unsaturated ethers, including vinyl methyl ether, vinyl ethyl ether, allyl glycidyl ether, etc.; vinyl cyanide compounds, including acrylonitrile, methacrylonitrile, α-chloroacrylonitrile, vinylidene cyanide, etc.; unsaturated amides, including acrylamide, methacrylamide, α-chloroacrylamide, N-2-hydroxyethyl acrylamide, N-2-hydroxyethyl methacrylamide, etc.; unsaturated imides, including maleimide, N-phenylmaleimide, N-cyclohexylmaleimide, etc.; aliphatic conjugated dienes, including 1,3-butadiene, isoprene, chloroprene, etc.; and macromonomers having a monoacryloyl group or monomethacryloyl group at the terminal of a polymer molecular chain, including polystyrene, polymethyl acrylate, polymethyl methacrylate, poly-n-butyl acrylate, poly-n-butyl methacrylate, polysiloxane, etc. These monomers may be used alone or in combination of two or more.

Examples of the binder resin include (meth)acrylic acid/methyl(meth)acrylate copolymer, (meth)acrylic acid/benzyl(meth)acrylate copolymer, (meth)acrylic acid/2-hydroxyethyl(meth)acrylate/benzyl(meth)acrylate copolymer, (meth)acrylic acid/methyl(meth)acrylate/polystyrene macromonomer copolymer, (meth)acrylic acid/methyl(meth)acrylate/polymethyl(meth)acrylate macromonomer copolymer, (meth)acrylic acid/benzyl(meth)acrylate/polystyrene macromonomer copolymer, (meth)acrylic acid/benzyl(meth)acrylate/polymethyl(meth)acrylate macromonomer copolymer, (meth)acrylic acid/2-hydroxyethyl(meth)acrylate/benzyl(meth)acrylate/polystyrene macromonomer copolymer, (meth)acrylic acid/2-hydroxyethyl(meth)acrylate/benzyl(meth)acrylate/polymethyl(meth)acrylate macromonomer copolymer, (meth)acrylic acid/styrene/benzyl(meth)acrylate/N-phenylmaleimide copolymer, (meth)acrylic acid/mono(2-acryloyloxy)succinate/styrene/benzyl(meth)acrylate/N-phenylmaleimide copolymer, (meth)acrylic acid/mono(2-acryloyloxyethyl)succinate/styrene/allyl(meth)acrylate/N-phenylmaleimide copolymer, (meth)acrylic acid/benzyl(meth)acrylate/N-phenylmaleimide/styrene/glycerolmono(meth)acrylate copolymer, etc.

Among these, particularly useful is (meth)acrylic acid/benzyl(meth)acrylate copolymer, (meth)acrylic acid/benzyl(meth)acrylate/styrene copolymer, (meth)acrylic acid/methyl(meth)acrylate copolymer, or (meth)acrylic acid/methyl(meth)acrylate/styrene copolymer.

The weight average molecular weight of the binder resin, in terms of polystyrene, is not particularly limited, but may fall in the range of 3,000˜100,000, preferably 3,000˜50,000, and more preferably 5,000˜50,000. When the weight average molecular weight of the binder resin falls in the range of 3,000˜100,000, it is easy to disperse the colorant, and low viscosity and superior storage stability may be obtained.

The amount of the binder resin is set to 1˜15 mass %, and preferably 2˜10 mass %, based on the photo-sensitive resin composition according to the present invention. When the amount of the binder resin is 1˜15 mass % based on the photo-sensitive resin composition according to the present invention, the colorant may be easily dispersed and storage stability becomes superior.

Dispersing Agent (C)

The dispersing agent is added to prevent flocculation of the colorant which is a white pigment and to maintain stability thereof.

The dispersing agent may include an acrylate-based dispersing agent, such as butyl methacrylate (BMA) or N,N-dimethylaminoethyl methacrylate (DMAEMA).

The acrylate-based dispersing agent may be prepared using a living control process as disclosed in Korean Unexamined Patent Publication No. 2004-0014311, and commercially available products of the acrylate-based dispersing agent prepared using a living control process include DISPER BYK-2000, DISPER BYK-2001, DISPER BYK-2070, DISPER BYK-2150, etc.

Also, examples of the dispersing agent may include known resin type pigment dispersing agents, in particular, oily dispersing agents, including polyurethane, polycarboxylic acid ester such as polyacrylate, unsaturated polyamide, polycarboxylic acid, (partial) amine salts of polycarboxylic acid, ammonium salts of polycarboxylic acid, alkylamine salts of polycarboxylic acid, polysiloxane, long-chain polyaminoamide phosphate, hydroxyl group-containing polycarboxylic acid ester and modified products thereof, or amides produced by the reaction between a free carboxyl group-containing polyester and a poly(lower alkyleneimine), or salts thereof; water-soluble resin or polymer compounds, including (meth)acrylic acid-styrene copolymer, (meth)acrylic acid-(meth)acrylate ester copolymer, styrene-maleic acid copolymer, polyvinyl alcohol or polyvinyl pyrrolidone; polyester; modified polyacrylate; ethylene oxide/propylene oxide adducts, and phosphate ester.

Commercially available products of the resin type pigment dispersing agent may include cationic resin dispersing agents, including those available from BYK Chemie: DISPER BYK-160, DISPER BYK-161, DISPER BYK-162, DISPER BYK-163, DISPER BYK-164, DISPER BYK-166, DISPER BYK-171, DISPER BYK-180, DISPER BYK-182,DISPER BYK-184; those available from BASF: EFKA-44, EFKA-46, EFKA-47, EFKA-48, EFKA-4010, EFKA-4050, EFKA-4055, EFKA-4020, EFKA-4015, EFKA-4060, EFKA-4300, EFKA-4330, EFKA-4400, EFKA-4406, EFKA-4510, EFKA-4800; those available from Lubirzol: SOLSPERS-24000, SOLSPERS-32550, NBZ-4204/10; those available from Kawaken Fine Chemicals: HINOACT T-6000, HINOACT T-7000, HINOACT T-8000; those available from Ajinomoto: AJISPUR PB-821, AJISPUR PB-822, AJISPUR PB-823; those available from Kyoeisha Chemical: FLORENE DOPA-17HF, FLORENE DOPA-15BHF, FLORENE DOPA-33, FLORENE DOPA-44, etc.

The dispersing agent may be included in an amount of 1˜10 mass %, and preferably 3˜7 mass %, based on the photo-sensitive resin composition. If the amount of the dispersing agent is less than 1 mass % based on the photo-sensitive resin composition, dispersibility of the white pigment may decrease. In contrast, if the amount thereof exceeds 10 mass %, mechanical properties of the applied bezel may deteriorate.

Photopolymerizable Compound (D)

The photopolymerizable compound is a compound which may be polymerized by the action of light and a photoinitiator, and may include a monofunctional monomer, a bifunctional monomer, and the other polyfunctional monomers.

Specific examples of the monofunctional monomer include nonylphenylcarbitol acrylate, 2-hydroxy-3-phenoxypropyl acrylate, 2-ethylhexylcarbitol acrylate, 2-hydroxyethyl acrylate, N-vinylpyrrolidone, etc., and commercially available products thereof include Aronix M-101 (Toagosei), KAYARAD TC-110S (Nippon Kayaku), Biscoat 158 (Osaka Yuki Kagaku Kogyo), etc.

Specific examples of the bifunctional monomer include 1,6-hexanediol di(meth)acrylate, ethylene glycol di(meth)acrylate, neopentyl glycol di(meth)acrylate, triethylene glycol di(meth)acrylate, bisphenol A bis(acryloyloxyethyl)ether, 3-methylpentanediol di(meth)acrylate, etc., and commercially available products thereof include Aronix M-210, M-1100, 1200 (Toagosei), KAYARAD HDDA (Nippon Kayaku), Biscoat 260 (Osaka Yuki Kagaku Kogyo), AH-600, AT-600, UA-306H (Kyoeisha Kagaku), etc.

Specific examples of the trifunctional or higher polyfunctional photopolymerizable compound include trimethylolpropane tri(meth)acrylate, ethoxylated trimethylolpropane tri(meth)acrylate, propoxylated trimethylolpropane tri(meth)acrylate, pentaerythritol tri(meth)acrylate, pentaerythritol tetra(meth)acrylate, dipentaerythritol penta(meth)acrylate, ethoxylated dipentaerythritol hexa(meth)acrylate, propoxylated dipentaerythritol hexa(meth)acrylate, dipentaerythritol hexa(meth)acrylate, dipentaerythritol hexaacrylate, etc., and commercially available products thereof include Aronix M-309, TO-1382 (Toagosei), KAYARAD TMPTA, KAYARAD DPHA, KAYARAD DPHA-40H (Nippon Kayaku), etc.

Among the above examples of the photopolymerizable compound, trifunctional or higher (meth)acrylic acid ester and urethane(meth)acrylate are useful because of superior polymerizability and enhanced strength.

These photopolymerizable compounds may be used alone or in combination of two or more. The photopolymerizable compound may be included in an amount of 1˜10 mass %, and preferably 3˜7 mass %, based on the photo-sensitive resin composition. If the amount of the photopolymerizable compound is less than 1 mass %, non-curing may occur. In contrast, if the amount thereof exceeds 10 mass %, adhesion and strength of the applied bezel may become poor.

Photoinitiator (E)

The photoinitiator may include one or more selected from the group consisting of a triazine-based compound, an acetophenone-based compound, a biimidazole-based compound, and an oxime compound.

Specific examples of the triazine-based compound may include 2,4-bis(trichloromethyl)-6-(4-methoxyphenyl)-1,3,5-triazine, 2,4-bis(trichloromethyl)-6-(4-methoxynathtyl)-1,3,5-triazine, 2,4-bis(trichloromethyl)-6-piperonyl-1,3,5-triazine, 2,4-bis(trichloromethyl)-6-(4-methoxystyryl)-1,3,5-triazine, 2,4-bis(trichloromethyl)-6-[2-(5-methylfuran-2-yl)ethenyl]-1,3,5-triazine, 2,4-bis(trichloromethyl)-6-[2-(furan-2-yl)ethenyl]-1,3,5-triazine, 2,4-bis(trichloromethyl)-6-[2-(4-diethylamino-2-methylphenyl)ethenyl]-1,3,5-triazine, 2,4-bis(trichloromethyl)-6-[2-(3,4-dimethoxyphenyl)ethenyl]-1,3,5-triazine, etc.

Specific examples of the acetophenone-based compound include diethoxyacetophenone, 2-hydroxy-2-methyl-1-phenylpropan-1-one, benzyldimethylketal, 2-hydroxy-1-[4-(2-hydroxyethoxy)phenyl]-2-methylpropan-1-one, 1-hydroxycyclohexylphenylketone, 2-methyl-1-(4-methylthiophenyl)-2-morpholinopropan-1-one, 2-benzyl-2-dimethylamino-1-(4-morpholinophenyl)butan-1-one, 2-hydroxy-2-methyl-1-[4-(1-methylvinyl)phenyl]propan-1-one, 2-(4-methylbenzyl)-2-(dimethylamino)-1-(4-morpholinophenyl)butan-1-one, etc.

Specific examples of the biimidazole compound include 2,2′-bis(2-chlorophenyl)-4,4′,5,5′-tetraphenylbiimidazole, 2,2′-bis(2,3-dichlorophenyl)-4,4′,5,5′-tetraphenylbiimidazole, 2,2′-bis(2-chlorophenyl)-4,4′,5,5′-tetra(alkoxyphenyl)biimidazole, 2,2′-bis(2-chlorophenyl)-4,4′,5,5′-tetra(trialkoxyphenyl)biimidazole, 2,2-bis(2,6-dichlorophenyl)-4,4′,5,5′-tetraphenyl-1,2′-biimidazole or imidazole compounds in which the phenyl group at 4,4′,5,5′ positions is substituted with a carboalkoxy group. Among these, 2,2′-bis(2-chlorophenyl)-4,4′,5,5′-tetraphenylbiimidazole, 2,2′-bis(2,3-dichlorophenyl)-4,4′,5,5′-tetraphenylbiimidazole, or 2,2-bis(2,6-dichlorophenyl)-4,4′,5,5′-tetraphenyl-1,2′-biimidazole is useful.

Specific examples of the oxime compound include o-ethoxycarbonyl-α-oxyimino-1-phenylpropan-1-one, etc., and commercially available products thereof include OXE01 and OXE02 from BASF.

Other photoinitiators known in the art may be additionally used so long as they do not deteriorate the effects of the invention. Furthermore, the photoinitiator may be used along with an assistant photoinitiator typical in the art.

The amount of the photoinitiator may be 1˜5 mass % based on the photo-sensitive resin composition according to the present invention. If the amount of the photopolymerizable compound is less than 1 mass %, non-curing may occur. In contrast, if the amount thereof exceeds 5 mass %, a polymerization rate becomes too fast, negatively affecting mechanical properties of the bezel.

Solvent (F)

The solvent is not particularly limited, and examples thereof may include ethers, aromatic hydrocarbons, ketones, alcohols, esters, or amides.

Specific examples of the solvent include ethers, including ethylene glycol monomethylether, ethylene glycol monoethylether, ethylene glycol monopropylether, ethylene glycol monobutylether, diethylene glycol dimethylether, diethylene glycol diethylether, diethylene glycol dipropylether, diethylene glycol dibutylether, etc.; aromatic hydrocarbons, including benzene, toluene, xylene, mesitylene, etc.; ketones, including methylethylketone, acetone, methylamylketone, methylisobutylketone, cyclohexanone, etc.; alcohols, including ethanol, propanol, butanol, hexanol, cyclohexanol, ethylene glycol, glycerin, etc.; esters, including 3-ethoxypropionic acid ethyl, 3-methoxypropionic acid methyl, methyl cellosolve acetate, ethyl cellosolve acetate, ethyl acetate, butyl acetate, amyl acetate, methyl lactate, ethyl lactate, butyl lactate, 3-methoxybutyl acetate, 3-methyl-3-methoxy-1-butylacetate, methoxypentyl acetate, ethylene glycol monoacetate, ethylene glycol diacetate, ethylene glycol monomethyl ether acetate, ethylene glycol monoethyl ether acetate, diethylene glycol monoacetate, diethylene glycol diacetate, diethylene glycol monobutyl ether acetate, propylene glycol monoacetate, propylene glycol diacetate, propylene glycol monomethyl ether acetate, propylene glycol monoethyl ether acetate, ethylene carbonate, propylene carbonate or γ-butyrolactone, etc. Among these solvents, taking into consideration applicability and drying properties, particularly useful is propylene glycol monomethyl ether acetate, propylene glycol monoethyl ether acetate, cyclohexanone, ethyl lactate, butyl lactate, 3-ethoxypropionic acid ethyl, or 3-methoxypropionic acid methyl. These solvents may be used alone or in combination of two or more.

The amount of the solvent may be 15˜43 mass %, and preferably 30˜40 mass %, based on the total amount of the resin composition including the same. If the amount of the solvent is less than 15 mass %, viscosity may increase. In contrast, if the amount thereof exceeds 43 mass %, it is difficult to adjust viscosity.

Additive (G)

The photo-sensitive resin composition according to the present invention may include at least one additive selected from the group consisting of a polymer compound, a curing agent, a surfactant, an adhesion accelerator, an antioxidant, a UV absorber, and an anti-flocculating agent, as necessary, in the range that does not change the purpose of the invention.

Specific examples of the polymer compound include a curable resin such as an epoxy resin, a maleimide resin or the like, and a thermoplastic resin such as polyvinyl alcohol, polyacrylic acid, polyethylene glycol monoalkyl ether, polyfluoroalkyl acrylate, polyester, polyurethane and so on.

When a photo-sensitive composition including the photo-sensitive resin composition according to the present invention is applied on an e-paper reflective plate, the curing agent functions to cure the core part and to enhance mechanical strength, and specific examples of the curing agent include an epoxy compound, a polyfunctional isocyanate compound, a melamine compound, an oxetane compound, etc.

Specific examples of the epoxy compound as the curing agent include bisphenol A type epoxy resin, hydrogenated bisphenol A type epoxy resin, bisphenol F type epoxy resin, hydrogenated bisphenol F type epoxy resin, novolac epoxy resin, other aromatic epoxy resins, alicyclic epoxy resin, glycidylester resin, glycidylamine resin, or bromide derivatives of the epoxy resin, aliphatic, alicyclic or aromatic epoxy compounds in addition to the epoxy resin and bromide derivatives thereof, butadiene (co)polymer epoxide, isoprene (co)polymer epoxide, glycidyl(meth)acrylate (co)polymer, triglycidyl isocyanurate, etc.

Specific examples of the oxetane compound as the curing agent include carbonate bisoxetane, xylene bisoxetane, adipate bisoxetane, terephthalate bisoxetane, cyclohexane dicarboxylic acid bisoxetane, etc.

The curing agent may be used along with an assistant curing compound which may cause the ring-opening polymerization of an epoxy group in epoxy compounds or an oxetane backbone in oxetane compounds. Examples of the assistant curing compound include polycarbonic acids, polycarbonic anhydrides, acid generators, etc. The polycarbonic anhydrides may include commercially available those of the epoxy resin curing agent. Specific examples of the epoxy resin curing agent include Adeka Hardener EH-700 (available from Adeka Corp.), Rikacid HH (available from New Japan Chemical Co. Ltd.), ME-700 (available from New Japan Chemical Co. Ltd.), etc. The exemplified curing agents may be used alone or in combination of two or more.

The surfactant may include a fluorine-based surfactant or a silicone-based surfactant.

Examples of the silicone-based surfactant include DC3PA, DC7PA, SH11PA, SH21PA, and SH8400 available from Dow Coming Toray Silicone; TSF-4440, TSF-4300, TSF-4445, TSF-4446, TSF-4460, and TSF-4452 available from GE Toshiba Silicone. Examples of the fluorine-based surfactant may include Megafac F-470, F-471, F-475, F-482, and F-489 available from Dai-Nippon Ink Kagaku Kogyo. The exemplified surfactants may be used alone or in combination of two or more.

Specific examples of the adhesion accelerator include vinyltrimethoxysilane, vinyltriethoxysilane, vinyltris(2-methoxyethoxy)silane, N-(2-aminoethyl)-3-aminopropyl methyl dimethoxysilane, N-(2-aminoethyl)-3-aminopropyl trimethoxysilane, 3-aminopropyl triethoxysilane, 3-glycidoxypropyl trimethoxysilane, 3-glycidoxypropyl methyldimethoxysilane, 2-(3,4-epoxycyclohexyl)ethyl trimethoxysilane, 3-chloropropyl methyl dimethoxysilane, 3-chloropropyl trimethoxysilane, 3-methacryloxypropyl trimethoxysilane, 3-mercaptopropyl trimethoxysilane, 3-isocyanatopropyl trimethoxysilane, 3-isocyanatopropyl triethoxysilane, etc. Specific examples of the antioxidant include 2,2′-thiobis(4-methyl-6-t-butylphenol), 2,6-di-t-butyl-4-methylphenol, etc.

Specific examples of the UV absorber include 2-(3-tert-butyl-2-hydroxy-5-methylphenyl)-5-chlorobenzotriazole, alkoxy benzophenone, etc.

Specific examples of the anti-flocculating agent include sodium polyacrylate.

The photo-sensitive resin composition including the above components may be prepared by mixing the colorant (A) including the white pigment, the binder resin (B), the dispersing agent (C) and the solvent (F), further adding the binder resin (B), the photopolymerizable compound (D), the photoinitiator (E), and the additive (G), and performing kneading and dispersion. The dispersion process may be performed by means of a longitudinal or transverse sand grinder, a pin mill, a slit mill, or an ultrasonic dispersion machine, using beads made of glass or zirconia having a diameter of 0.01˜1 mm. Before dispersion of the beads, kneading dispersion treatment may be carried out while imparting strong shear force using a two-roll mill, a three-roll mill, a ball mill, a trom mill, a disperser, a kneader, a cokneader, a homogenizer, a blender, a single- or twin-screw extruder.

The bezel for TSM according to the present invention has a pattern layer formed by applying the photo-sensitive resin composition on a substrate, and performing exposure and development in a predetermined pattern. The photo-sensitive resin composition includes 50 mass % or more of TiO₂ based on the solid content thereof, and 45 mass % or more of TiO₂ based on the total amount of the composition including the solvent. This resin composition may have a viscosity of about 2˜30 cps. Even when this composition is applied thinly, superior whiteness may be obtained, resulting in high coating workability.

The substrate may include one typically used in the art, for example, a glass substrate, PET (Poly ethylene terephthalate), LCP (Liquid-crystal polymers), or PC (Poly Carbonate), which may be used alone or in a state of being deposited with metal. The deposited metal typically includes aluminum, silver, platinum, indium tin oxide (ITO), etc. The thickness of the substrate is not limited, and is typically set to about 1 mm.

Applying the photo-sensitive resin composition on the substrate may be performed using a coating process, such as spinning, spinning after slitting, slitting, rolling, spraying, or ink-jetting. After application of the photo-sensitive resin composition on the substrate, the volatile component such as the solvent may be volatilized, thus forming a photo-sensitive resin layer. In order to easily volatilize the volatile component, heating at 30˜150° C. for 10 sec˜5 min may be carried out.

The thickness of the applied photo-sensitive resin composition is determined depending on the applying conditions such as the viscosity of the composition, the concentration of the solid, the application rate, etc., and may be set to 3˜15 to but is not necessarily limited thereto. In order to perform efficient coating in the above thickness range, the viscosity may be set to 2˜30 cps. If the thickness of the applied photo-sensitive resin composition is higher, it is not easy to form a sensor electrode. In contrast, if the thickness thereof is lower, whiteness may decrease.

Subsequently, the photo-sensitive resin layer is exposed to light. Although not necessarily limited, this exposure process may be performed by radiating light rays onto the photo-sensitive resin layer via a photomask in a predetermined pattern. The light rays may include g rays (wavelength: 436 nm), h rays, and i rays (wavelength: 365 nm), of UV rays. The UV rays may be radiated at 10˜300 mJ/cm² for 1˜60 sec.

After completion of the exposure process, the non-exposed region is removed via development, thus forming a pattern layer. This development process may be conducted by immersing the exposed photo-sensitive resin layer in a developing solution. The developing solution may be an aqueous solution of an alkali compound, for example, sodium carbonate, sodium hydroxide, potassium hydroxide, potassium carbonate, tetramethylammonium hydroxide, etc.

After completion of the development process, the pattern layer is washed with water and dried, after which heating may be carried out, as necessary. Heating treatment may enhance the mechanical strength of the pattern layer. The heating treatment may be conducted at 120° C. or higher, and preferably 150˜250° C., for 10˜60 min.

The substrate having the pattern layer formed as above is appropriate for use in a bezel for TSM. Even when the composition is applied thinly, whiteness represented by L* may be 85% or more.

The following examples which are set forth to illustrate but are not to be construed as limiting the present invention may provide a better understanding of the present invention.

### PREPARATION EXAMPLE 1

Preparation of Modified TiO₂

To a solution comprising water (15%), ethanol (84%), and aqueous ammonia (1%), TiO₂ (Dupont R706) was added in an amount of 15% of the solution, after which vinyltriethoxysilane was added in an amount of 1.5% of TiO₂, and the resulting mixture was stirred for 12 hr. Thereafter, polypropylene glycol dimethacrylate was added in an amount of 5% of TiO₂, along with a photoinitiator (Irgacure 369), and then additionally stirred. The resulting mixture was exposed to light at 100˜200 mJ/cm² (including all of i, g, and h lines), thus preparing surface-modified TiO₂. The surface-modified TiO₂ was centrifuged using ethanol in the form of being dispersed in a solvent, and then re-dispersed, so that unreactants were washed, thus obtaining pure modified TiO₂.

### EXAMPLE 1

The surface-modified TiO₂ (51 mass %) of Preparation Example 1, 1 mass % of a dispersing agent BYK180 and 2 mass % of an alkali water-soluble binder resin (SUN3004, available from Miwon Commercial Co. Ltd.) were dissolved in 36 mass % of propylene glycol monomethyl ether acetate (PGMEA) (solid content of about 60%), and then dispersed using a bead mill for 1 hr, thus preparing a dispersion solution. Subsequently, 3.5 mass % of an alkali water-soluble binder resin (SUN3004, available from Miwon Commercial Co. Ltd.), 4 mass % of dipentaerythritol hexaacrylate (DPHA, available from Miwon Specialty Chemical Co. Ltd.), and 1 mass % of Irgacure 819 (Ciba) and 1 mass % of Irgacure 184 (Ciba) as photoinitiators were added, thus preparing a white photo-sensitive resin composition containing 45 mass % of TiO₂. Then, a leveling agent, BYK 399, was added in an amount of 0.5 mass % based on the total amount of the composition. The viscosity of the composition was 15 cps.

The TiO₂ photo-sensitive resin composition was applied on a glass substrate using spin coating, thus forming a white layer. Then, the solvent was removed at 100° C. for 10 min. A photomask was placed on the thin film and then irradiated with UV rays. As such, the UV light source was 1 KW high-pressure Hg lamp including all of g, h and i rays at 150 mJ/cm². Then, a development process was conducted under conditions of a development temperature of 25° C., a development time of 60 sec, a water washing time of 60 sec, and spin drying of 25 sec using a developer. As such, a developing solution was 1 mass % of an aqueous potassium hydroxide solution. Subsequently, thermosetting was conducted at 200° C. for 1 hr. The thickness of the thin bezel was 8 μm, and the measured whiteness (L*) was 90%.

### COMPARATIVE EXAMPLE 1

Upon preparing a TiO₂ photo-sensitive resin composition, TiO₂ dispersed using a dispersing agent BYK 180 was used instead of the modified TiO₂ of Preparation Example 1. Specifically, 2 mass % of BYK 180 was dissolved in propyleneglycol monomethyl ether acetate and then TiO₂ was added in an amount of 40% based on the total amount of the solution, and the resulting mixture was then stirred using a homogenizer for about 20 min. Subsequently, the mixture was dispersed for 1 hr using a bead mill, thus preparing a dispersion solution. This solution was added with the photo-sensitive materials as in Example 1, thus preparing the TiO₂ photo-sensitive resin composition (ink).

[Dispersion Stability]

Each of the dispersion solution and the ink was placed in an amount of 10 mg in a vial, followed by measuring a period of time required to generate phase separation via precipitation at the top of the solution at room temperature and 60° C. The results are shown in Table 1 below.

TABLE 1

| | Ex. 1 | | Comp. Ex. 1 | | | |
|---|---|---|---|---|---|---|
| | Dispersion Sol. | Ink | Dispersion Sol. | | Ink | |
| Room Temp. | <4 days | <3 days | <1 | day | <1 | day |
| 60° C. | <2.5 days | <2 days | ~10 | hr | ~6 | hr |

The photo-sensitive resin composition for a bezel of a touch screen module according to the present invention exhibited superior dispersion stability. Even when a pattern layer formed using the composition is thin, whiteness represented by L* is 85% or more, and thus the composition of the invention is very suitable for use in a bezel of a touch screen module.

As described hereinbefore, the present invention provides a photo-sensitive resin composition for a bezel of a touch screen module and a bezel for a touch screen module using the same. According to the present invention, the photo-sensitive resin composition can exhibit superior dispersion stability. Furthermore, even when a pattern layer is formed thinly using the above composition, whiteness represented by L* can be 85% or more. Therefore, the photo-sensitive resin composition according to the present invention can be effectively utilized in a bezel for a touch screen module.

Although the embodiments of the present invention have been disclosed for illustrative purposes, those skilled in the art will appreciate that a variety of different modifications, additions and substitutions are possible, without departing from the scope and spirit of the invention as disclosed in the accompanying claims.

Accordingly, such modifications, additions and substitutions should also be understood as falling within the scope of the present invention.

What is claimed is:

1. A photo-sensitive resin composition for a bezel of a touch screen module, comprising a colorant composed of surface-modified TiO₂, a binder resin, a dispersing agent, a photopolymerizable compound, a photoinitiator, and a solvent, and having a viscosity of 2˜30 cps and a solid content of 50˜90 mass %.

2. A photo-sensitive resin composition, comprising 45˜80 mass % of a colorant composed of surface-modified TiO₂, 1˜15 mass % of a binder resin, 1˜10 mass % of a dispersing agent, 1˜10 mass % of a photopolymerizable compound, 1˜5 mass % of a photoinitiator, and 15˜43 mass % of a solvent.

3. The photo-sensitive resin composition of claim 1, wherein the TiO₂ is surface-treated with at least one selected from the group consisting of SiO₂, Al₂O₃, ZrO₂, ZnO and an organic material.

4. The photo-sensitive resin composition of claim 3, wherein the surface-treated TiO₂ has 75˜95 mass % of TiO₂ core.

5. The photo-sensitive resin composition of claim 1, wherein the colorant is used in an amount of 50˜90 mass % based on the solid content of the composition.

6. The photo-sensitive resin composition of claim 1, further comprising at least one additive selected from the group consisting of a polymer compound, a curing agent, a surfactant, an adhesion accelerator, an antioxidant, a UV absorber, and an anti-flocculating agent

7. A bezel for a touch screen module, including a pattern layer formed by applying the photo-sensitive resin composition of claim 1 on a substrate, and performing exposure and development in a predetermined pattern.

8. A bezel for a touch screen module, including a pattern layer formed by applying the photo-sensitive resin composition of claim 2 on a substrate, and performing exposure and development in a predetermined pattern.

9. A bezel for a touch screen module, including a pattern layer formed by applying the photo-sensitive resin composition of claim 3 on a substrate, and performing exposure and development in a predetermined pattern.

10. A bezel for a touch screen module, including a pattern layer formed by applying the photo-sensitive resin composition of claim 4 on a substrate, and performing exposure and development in a predetermined pattern.

11. A bezel for a touch screen module, including a pattern layer formed by applying the photo-sensitive resin composition of claim 5 on a substrate, and performing exposure and development in a predetermined pattern.

12. A bezel for a touch screen module, including a pattern layer formed by applying the photo-sensitive resin composition of claim 6 on a substrate, and performing exposure and development in a predetermined pattern.

13. The bezel of claim 7, wherein the bezel has a thickness of 3˜15 μm.

14. The bezel of claim 8, wherein the bezel has a thickness of 3˜15 μm.

15. The bezel of claim 7, wherein the bezel has a whiteness of 85% or more as measured by reflectance.

16. The bezel of claim 8, wherein the bezel has a whiteness of 85% or more as measured by reflectance.
